(19) United States
(12) Patent Application Publication
(10) Pub. No.: US 2006/0266498 A1
(43) Pub. Date: Nov. 30, 2006

(54) LIQUID COOLING SYSTEM SUITABLE FOR REMOVING HEAT FROM ELECTRONIC COMPONENTS

(76) Inventors: Tay-Jian Liu, Shenzhen (CN); Chih-Peng Lee, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/306,914

(22) Filed: Jan. 16, 2006

(30) Foreign Application Priority Data
May 27, 2005 (TW) 094117383

(51) Int. Cl. H05K 7/20

(52) U.S. Cl. 165/80.4; 361/699

(57) ABSTRACT

A liquid cooling system (30) for removing heat from a heat-generating component is disclosed. The liquid cooling system includes a heat-absorbing member (50) defining therein a fluid flow channel (54) for passage of a coolant. The fluid flow channel includes a plurality of passage segments (54a, 54b, 54c) arranged from a center portion to a peripheral portion of the heat-absorbing member. Every two adjacent passage segments are in fluid communication with each other in such a manner that, when the coolant flows from one passage segment to enter into an adjacent passage segment, the coolant is divided into at least two currents flowing in different directions in the adjacent passage segment.

### FIELD OF THE INVENTION

The present invention relates generally to an apparatus for dissipation of heat from heat-generating components, and more particularly to a liquid cooling system suitable for removing heat from electronic components of computers.

### DESCRIPTION OF RELATED ART

Currently, liquid cooling systems are widely used for removing heat from electronic components such as central process units (CPUs) of computers. A liquid cooling system generally includes a heat-absorbing member, a heat-dissipating member, a pump and a plurality of connecting tubes. These individual components are connected together so as to form a heat transfer loop. The liquid cooling system employs a coolant circulating through the heat transfer loop so as to continuously bring thermal energy absorbed by the heat-absorbing member to the heat-dissipating member where the thermal energy is dissipated.

In practice, the heat-absorbing member is maintained in thermal contact with a heat-generating component (e.g., a CPU) for absorbing the heat generated by the CPU. In order to improve the heat transfer effect of the heat-absorbing member, a fluid flow channel having a plurality of turns is generally defined in the heat-absorbing member for passage of the coolant. As the coolant flows through the fluid flow channel, the heat of the CPU is received by the coolant, which then carries the heat to the heat-dissipating member for dissipation.

FIG. 10 illustrates a fluid flow channel 10 defined in a conventional heat-absorbing member. The fluid flow channel 10 is defined by disposing a plurality of parallel partition plates 11 into a rectangular, concaved enclosure 12. An inlet hole and an outlet hole (not labeled) are defined in diagonal corners of the heat-absorbing member, respectively. The coolant enters the heat-absorbing member via the inlet hole, then flows through the fluid flow channel 10 and finally escapes the heat-absorbing member via the outlet hole. FIG. 11 illustrates a fluid flow channel 20 defined in another conventional heat-absorbing member. This fluid flow channel 20 is directly defined by making a spiral groove in a solid metal block via mechanical machining. Also, an inlet hole and an outlet hole (not labeled) are formed at two ends of the fluid flow channel 20 for coolant to enter into and escape from the fluid flow channel 20, respectively.

Each of the above-mentioned fluid flow channels 10, 20 has a singular one-way configuration. As the coolant flows in these fluid flow channels 10, 20, the coolant is accordingly restricted in a singular direction defined by each of the fluid flow channels 10, 20. As a result, the coolant flowing in the fluid flow channels 10, 20 encounters much flow resistance and suffers great pressure drop. The pump connected in the heat transfer loop is thus required to provide a large driving force for driving the coolant to circulate through the heat transfer loop, and therefore consume more energy. On the other hand, if the coolant is not brought to flow through the fluid flow channels 10, 20 rapidly, the thermal resistance associated with the corresponding heat-absorbing member will increase.

Therefore, it is desirable to provide a liquid cooling system which overcomes the foregoing disadvantages.

### SUMMARY OF INVENTION

The present invention relates to a liquid cooling system for removing heat from a heat-generating component. The liquid cooling system includes a heat-absorbing member defining therein a fluid flow channel for passage of a coolant. The fluid flow channel includes a plurality of passage segments arranged from a center portion to a peripheral portion of the heat-absorbing member. Every two adjacent passage segments are in fluid communication with each other in such a way that, when the coolant flows from one passage segment to enter into an adjacent passage segment, the coolant is divided into at least two currents flowing in different directions in the adjacent passage segment.

In one embodiment, every two adjacent passage segments are separated from each other by a partition member, with one passage segment being surrounded by the other passage segment. The partition member defines therein at least one cutout extending from the one passage segment to the other passage segment whereby the one passage segment is in fluid communication with the other passage segment.

Other advantages and novel features of the present invention will become more apparent from the following detailed description of preferred embodiment when taken in conjunction with the accompanying drawings, in which:

### BRIEF DESCRIPTION OF DRAWINGS

FIG. 1 is a schematic, isometric view of a liquid cooling system in accordance with one embodiment of the present invention;

FIG. 2 is a top cross-sectional view of a fluid flow channel defined in a heat-absorbing member in accordance with a first embodiment of the present invention;

FIG. 3 is a top cross-sectional view of a fluid flow channel defined in a heat-absorbing member in accordance with a second embodiment of the present invention;

FIG. 4 is a top cross-sectional view of a fluid flow channel defined in a heat-absorbing member in accordance with a third embodiment of the present invention;

FIG. 5 is a top cross-sectional view of a fluid flow channel defined in a heat-absorbing member in accordance with a fourth embodiment of the present invention;

FIG. 6 is a top cross-sectional view of a fluid flow channel defined in a heat-absorbing member in accordance with a fifth embodiment of the present invention;

FIG. 7 is a top cross-sectional view of a fluid flow channel defined in a heat-absorbing member in accordance with a sixth embodiment of the present invention;

FIG. 8 is a top cross-sectional view of a fluid flow channel defined in a heat-absorbing member in accordance with a seventh embodiment of the present invention;

FIG. 9 is a top cross-sectional view of a fluid flow channel defined in a heat-absorbing member in accordance with an eighth embodiment of the present invention;

FIG. 10 is a top cross-sectional view of a fluid flow channel defined in a heat-absorbing member in accordance with the conventional art; and

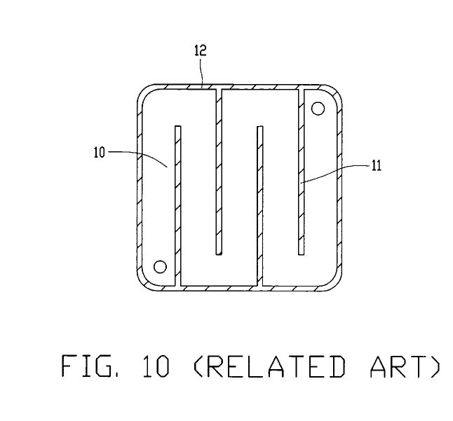

FIG. 11 is a top cross-sectional view of another fluid flow channel defined in a heat-absorbing member in accordance with the conventional art.

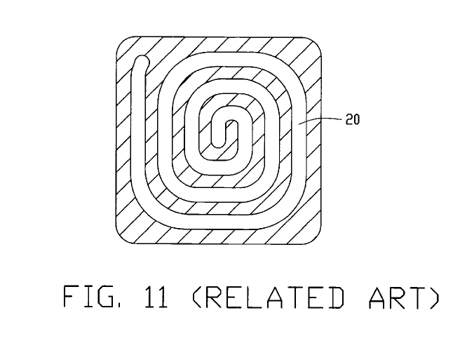

### DETAILED DESCRIPTION

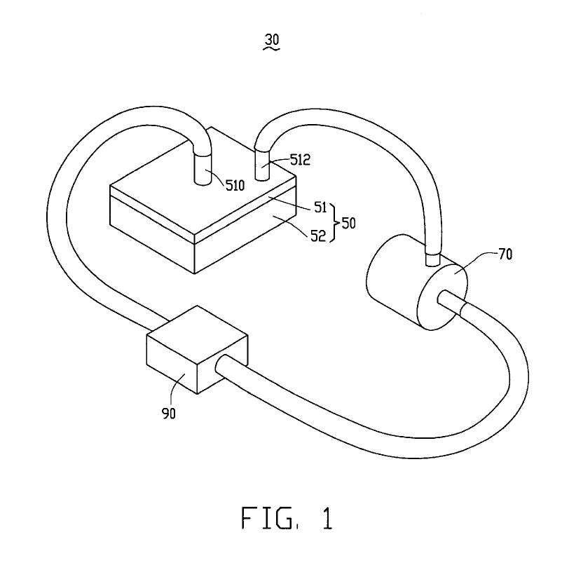

FIG. 1 schematically illustrates a liquid cooling system 30 in accordance with one embodiment of the present invention. The liquid cooling system 30 includes a heat-absorbing member 50, a heat-dissipating member 70 and a pump 90. These individual components are connected together via a plurality of connecting tubes (not labeled) so as to form a heat transfer loop. A coolant such as water is filled into the heat-absorbing member 50 and is circulated through the heat transfer loop under the driving of the pump 90. In operation, the heat-absorbing member 50 is maintained in thermal contact with a heat-generating component (not shown) such a CPU of a computer. In practice, a bottom face of a central portion of the heat-absorbing member 50 is brought to intimately contact with the CPU. The coolant contained in the heat-absorbing member 50 receives the heat generated by the CPU and then carries the heat to the heat-dissipating member 70 where the heat is dissipated to ambient environment. Although the heat-dissipating member 70 is schematically shown, it is well known by those skilled in the art that the heat-dissipating member 70 may be any cooling device such as a plurality of metal fins. After releasing the heat, the coolant is brought back to the heat-absorbing member 50 again under the driving of the pump 90, thus continuously taking the heat away from the CPU.

The heat-absorbing member 50 includes an upper portion 51 and a lower portion 52 hermetically connected to the upper portion 51. The heat-absorbing member 50 has a shortened inlet tube 510 and a shortened outlet tube 512 for providing communications for the coolant to enter into and exit the heat-absorbing member 50, respectively. Both the inlet tube 510 and the outlet tube 512 are connected to the upper portion 51 of the heat-absorbing member 50, with the inlet tube 510 located at a central portion of the upper portion 51.

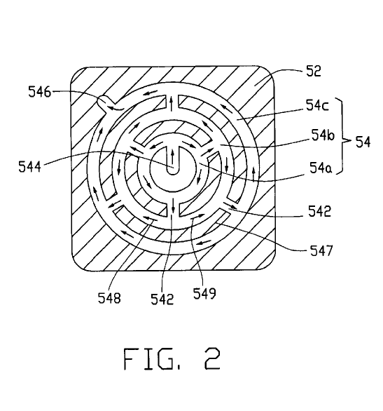

With reference also to FIG. 2, the lower portion 52 of the heat-absorbing member 50 defines therein a fluid flow channel 54 for passage of the coolant through the heat-absorbing member 50. The fluid flow channel 54 includes a plurality of passage segments arranged from a center portion to a peripheral portion of the heat-absorbing member 50. These passage segments includes first, second and third passage segments 54a, 54b, 54c consecutively and concentrically arranged from the central portion to the peripheral portion of the heat-absorbing member 50. Each of these passage segments 54a, 54b, 54c has a circular configuration. As with two adjacent passage segments, the one passage segment located closer to the peripheral portion of the heat-absorbing member 50 surrounds the other passage segment. The fluid flow channel 54 has an inlet hole 544 and an outlet hole 546 arranged at two ends thereof for communicating with the inlet tube 510 and the outlet tube 512, respectively. Generally, the fluid flow channel 10 is defined in the lower portion 52 of the heat-absorbing member 50 by milling a solid metal block, whereby a partition plate 547 is formed between every two adjacent grooves. Thus, every two adjacent passage segments, such as the first and second passage segments 54a, 54b or the second and third passage segments 54b, 54c, are separated from each other by the partition plate 547 located therebetween. Each of the partition plates 548 defines therein a plurality of cutouts 542 interconnecting one passage segment with the adjacent passage segment whereby the one passage segment is in fluid communication with the adjacent passage segment. All of the cutouts 542 defined in the heat-absorbing member 50 are radially oriented. The cutouts 542 extending from the first passage segment 54a to the second passage segment 54b and the cutouts 542 extending from the second passage segment 54b to the third passage segment 54c are arranged in a staggered manner. In this embodiment, each partition plate 547 defines three cutouts 542 therein, which are equidistantly spaced from each other.

Due to the presence of these cutouts 542, every two adjacent passage segments is capable of communicating with each other in such a manner that, when the coolant flows from one passage segment to enter into the adjacent passage segment, the coolant is divided into at least two currents flowing in different directions in the adjacent passage segment. For example, as the coolant flows from the first passage segment 54a to enter into the second passage segment 54b via the cutout 542 vertically downwardly as viewed from FIG. 2, the coolant is thrown against an inner wall of the partition plate 547 located between the second and third passage segments 54b, 54c. After impinging on the partition plate 547, the coolant is consequently divided into two currents as indicated by arrows 548, 549. The two currents flow in different directions (i.e., in opposite directions) in the second passage segment 54b. In this figure, all of the arrows shown including the arrows 548, 549 are indicative of the possible directions followed by the coolant as it flows through the fluid flow channel 54. In this embodiment, each of the partition plates 547 is divided substantially evenly into multiple (i.e., three) sections by the multiple (i.e., three) cutouts 542.

In the present liquid cooling system 30, the coolant contained in the heat transfer loop enters into the heat-absorbing member 50 via the inlet tube 510. Then the coolant flows sequentially from the inlet hole 544 of the fluid flow channel 54 to the first passage segment 54a, then to the second passage segment 54b, to the third passage segment 54c and to the outlet hole 546, and finally escapes the heat-absorbing member 50 via the outlet tube 512. The coolant is capable of moving from the central portion to the peripheral portion of the heat-absorbing member 50 rapidly through the cutouts 542, which significantly lowers the flow resistance and the pressure drop associated with the coolant as it flows through the fluid flow channel 54. Thus, a relatively small driving force output from the pump 90 may be enough for driving the coolant to flow along the heat transfer loop rapidly. The inlet tube 510 is vertically oriented toward the central portion of the lower portion 52 of the heat-absorbing member 50, which usually is brought to directly contact with the CPU and accordingly is the hottest spot of the heat-absorbing member 50. Thus, the coolant from the pump 90 can firstly directly impinge on the hottest spot of the heat-absorbing member 50, whereby the heat of the heat-absorbing member 50 and accordingly the CPU can be quickly and efficiently moved away. In conclusion, by the design that the inlet tube 510 is set at the top of the central portion of the heat-absorbing member 50 and the fluid flow channel 54 is configured as a plurality of concentric passage segments 54a, 54b, 54c which are interconnected by a plurality of cutouts 542, the heat of the CPU, which contacts with the bottom face of the central portion of the heat-absorbing member 50, can be quickly and efficiently removed away by the coolant flowing through the fluid flow channel 54.

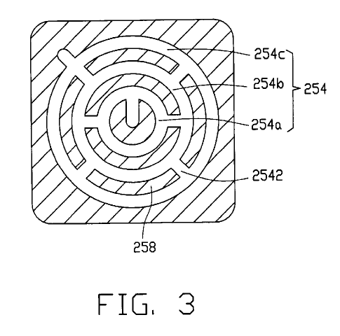

FIGS. 3-9 illustrate certain additional embodiments regarding the fluid flow channel 54. As shown in FIG. 3, the fluid flow channel 254 includes first, second and third passage segments 245a, 254b, 254c consecutively and concentrically arranged from the central portion to the peripheral portion of the heat-absorbing member 50. Every two adjacent passage segments communicates with each other by the radial cutouts 2542 defined in the partition plates 258. In this embodiment, there are four cutouts 2542 extending from the second passage segment 254b to the third passage segment 254c and two cutouts 2542 extending from the first passage segment 254a to the second passage segment 254b. That is, the number of cutouts 2542 extending from the second passage segment 254b to the third passage segment 254c is larger than the number of cutouts 2542 extending from the first passage segment 254a to the second passage segment 254b.

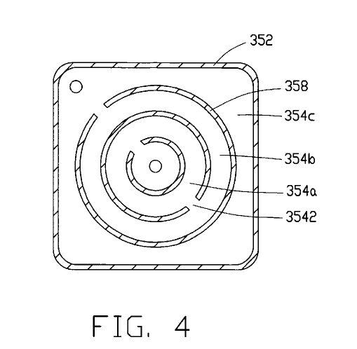

With referent to FIG. 4, the fluid flow channel defined in the heat-absorbing member 50 is made by disposing a plurality of partition plates 358 into an enclosed hollow metal housing 352. The fluid flow channel includes first, second and third passage segments 354a, 354b, 354c consecutively and concentrically arranged from the central portion to the peripheral portion of the heat-absorbing member 50. Each of the partition plates 358 placed in the metal housing 352 defines therein a cutout 3542 for providing communication between two adjacent passage segments.

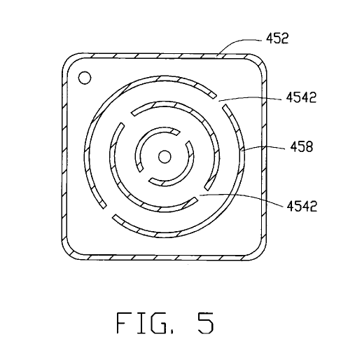

The fluid flow channel as shown in FIG. 5 has a similar configuration with the fluid flow channel as disclosed in FIG. 4. However, the fluid flow channel disclosed in FIG. 5 has two cutouts 4542 defined in each of the partition plates 458 disposed in the enclosed hollow metal housing 452.

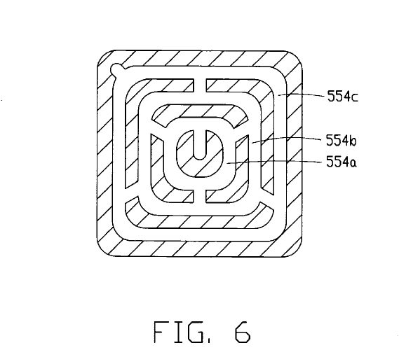

With referent to FIG. 6, the fluid flow channel includes first, second and third passage segments 554a, 554b, 554c consecutively and concentrically arranged from the central portion to the peripheral portion of the heat-absorbing member 50. By contrast with the fluid flow channel 54 as shown in FIG. 2, these passage segments 554a, 554b, 554c each have a rectangular configuration.

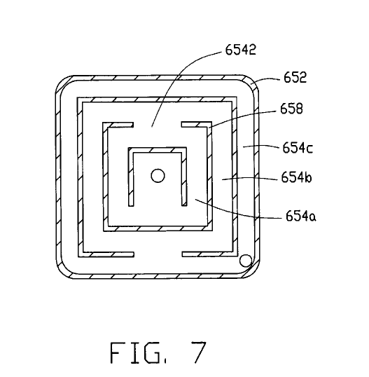

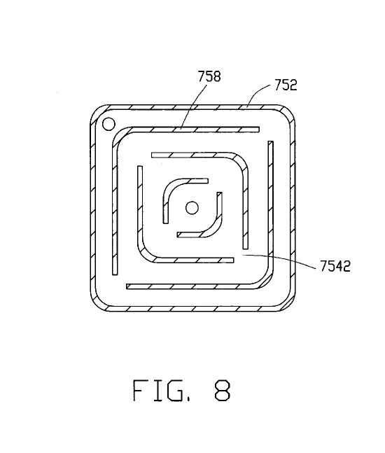

With referent to FIG. 7, the fluid flow channel is made by disposing a plurality of partition plates 658 into an enclosed hollow metal housing 652. The fluid flow channel includes first, second and third passage segments 654a, 654b, 654c consecutively and concentrically arranged from the central portion to the peripheral portion of the heat-absorbing member 50. Each of the partition plates 658 is substantially rectangular and has a cutout 6542 defined at a sidewall of the corresponding partition plate 658. FIG. 8 discloses a fluid flow channel similar with the fluid flow channel as disclosed in FIG. 7. However, the fluid flow channel disclosed in FIG. 8 has a pair of cutouts 7542 diagonally defined in each of the partition plates 758 disposed in the enclosed hollow metal housing 752.

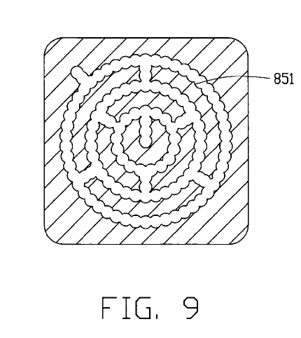

Referring now to FIG. 9, similar to FIG. 2, the fluid flow channel includes a plurality of circular, concentric passage segments. However, the lower portion 52 of the heat-absorbing member 50 has a pair of corrugated sidewalls 851 defining each of these passage segments. This design helps to increase contacting area between the heat-absorbing member 50 and the coolant flowing therethrough, whereby the coolant can take more heat away from the heat-absorbing member 50.

Although the fluid flow channel as mentioned in the forgoing specific embodiments are disclosed to be formed at the lower portion 52 of the heat-absorbing member 50, it should be recognized that the fluid flow channel may also be formed at the upper portion 51 of the heat-absorbing member 50 or formed at both of the upper and lower portions 51, 52 of the heat-absorbing member 50.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A liquid cooling system comprising a heat-absorbing member defining therein a fluid flow channel for passage of a coolant, the fluid flow channel including a plurality of passage segments arranged from a center portion to a peripheral portion of the heat-absorbing member, every two adjacent passage segments being separated from each other by a partition member with one passage segment being surrounded by the other passage segment, the partition member defining therein at least one cutout extending from the one passage segment to the other passage segment whereby the one passage segment is in fluid communication with the other passage segment.

2. The liquid cooling system of claim 1, wherein said plurality of passage segments are substantially circular and concentric.

3. The liquid cooling system of claim 1, wherein said plurality of passage segments includes first, second and third passage segments consecutively arranged from the central portion to the peripheral portion of the heat-absorbing member, and the cutout extending from the first passage segment to the second passage segment and the cutout extending from the second passage segment to the third passage segment are arranged in a staggered manner.

4. The liquid cooling system of claim 3, wherein the number of cutout extending from the second passage segment to the third passage segment is no less than the number of cutout extending from the first passage segment to the second passage segment.

5. The liquid cooling system of claim 1, wherein the partition member defines therein multiple cutouts and the partition member is divided substantially evenly into multiple sections by the multiple cutouts.

6. The liquid cooling system of claim 1, wherein said plurality of passage segments are substantially rectangular and concentric.

7. The liquid cooling system of claim 6, wherein the partition member is substantially rectangular and the cutout is defined at a corner of the partition member.

8. The liquid cooling system of claim 6, wherein the partition member is substantially rectangular and the cutout is defined at a sidewall of the partition member.

9. The liquid cooling system of claim 1, wherein the heat-absorbing member has corrugated sidewalls defining at least one of the passage segments.

10. A liquid cooling system comprising a heat-absorbing member defining therein a fluid flow channel for passage of a coolant, the fluid flow channel including a plurality of passage segments, every two adjacent passage segments being in fluid communication with each other in such a manner that, when the coolant flows from one passage segment to enter into an adjacent passage segment, the coolant is divided into at least two currents flowing in different directions in the adjacent passage segment.

11. The liquid cooling system of claim 10, wherein said plurality of passage segments are concentrically arranged from a center portion to a peripheral portion of the heat-absorbing member.

12. The liquid cooling system of claim 11, wherein said fluid flow channel further includes a plurality of radial cutouts defined in the heat-absorbing member and said plurality of passage segments are in fluid communication via said radial cutouts.

13. The liquid cooling system of claim 10, wherein said plurality of passage segments each have a substantially circular configuration.

14. The liquid cooling system of claim 10, wherein said plurality of passage segments each have a substantially rectangular configuration.

15. The liquid cooling system of claim 10, wherein the fluid flow channel is defined in the heat-absorbing member by milling a solid metal block.

16. The liquid cooling system of claim 10, wherein the fluid flow channel is defined in the heat-absorbing member by disposing a plurality of partition plates into an enclosed hollow housing.

17. A liquid cooling system comprising:
a heat-absorbing member having a first face adapted for engaging with a heat-generating electronic component and a second face provided with a liquid inlet through which liquid can flow into the heat-absorbing member, and a liquid outlet through which the liquid can leave the heat-absorbing member; and
a pump fluidically connecting with the inlet and outlet for driving the liquid to flow through the heat-absorbing member; wherein
the inlet and outlet are connected with each other through a fluid flow channel defined in the heat-absorbing member, the fluid flow channel comprising at least two concentric passage segments with an inner passage segment communicating with the inlet and an outer passage segment communicating with the outlet, at least a cutout interconnecting the at least two concentric passage segments.

18. The liquid cooling system of claim 17, wherein the heat-absorbing member has corrugated walls defining the fluid flow channel.

19. The liquid cooling system of claim 17, wherein the outlet is located at a peripheral portion of the heat-absorbing member.

20. The liquid cooling system of claim 17, wherein the inlet is located at a central portion of the heat-absorbing member.
